(19) United States
(12) Patent Application Publication
(10) Pub. No.: US 2026/0123299 A1
(43) Pub. Date: Apr. 30, 2026

(54) METHOD FOR MAKING SEMICONDUCTOR DEVICE INCLUDING AN ENRICHED SILICON 28 EPITAXIAL LAYER

(71) Applicant: Atomera Incorporated, Los Gatos, CA (US)

(72) Inventors: Marek HYTHA, Brookline, MA (US); Nyles Wynn CODY, Tempe, AZ (US); Keith Doran WEEKS, Chandler, AZ (US); Robert J. MEARS, Wellesley, MA (US)

(21) Appl. No.: 19/024,696

(22) Filed: Jan. 16, 2025

Related U.S. Application Data
(60) Provisional application No. 63/621,809, filed on Jan. 17, 2024.

(51) Int. Cl. H10P 14/20; H10D 30/01; H10D 62/815; H10P 90/00

(52) U.S. Cl. CPC H10P 14/3411; H10D 30/027; H10D 62/8162; H10P 14/3824; H10P 90/1906

(57) ABSTRACT

A method for making a semiconductor device may include growing ²⁸Si on a semiconductor layer, intermixing the ²⁸Si in the semiconductor layer, and thinning the semiconductor layer after intermixing. The method may further include repeating growing, intermixing, and thinning until a concentration of ²⁸Si in the semiconductor layer reaches a target concentration.

### CROSS-REFERENCE TO RELATED APPLICATION

This application claims the benefit of U.S. provisional app. No. 63/621,809 filed Jan. 17, 2024, which is hereby incorporated herein in its entirety by reference.

### TECHNICAL FIELD

The present disclosure generally relates to semiconductor devices and, more particularly, to semiconductor devices with enhanced semiconductor materials and associated methods.

### BACKGROUND

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fractional or binary or a binary compound semiconductor layer, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electroluminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

U.S. Pat. No. 7,105,895 to Wang et al. discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc., can be tailored to yield new aperiodic materials with desirable band-structure characteristics. Other parameters, such as electrical conductivity, thermal conductivity and dielectric permittivity or magnetic permeability are disclosed as also possible to be designed into the material.

Furthermore, U.S. Pat. No. 6,376,337 to Wang et al. discloses a method for producing an insulating or barrier layer for semiconductor devices which includes depositing a layer of silicon and at least one additional element on the silicon substrate whereby the deposited layer is substantially free of defects such that epitaxial silicon substantially free of defects can be deposited on the deposited layer. Alternatively, a monolayer of one or more elements, preferably comprising oxygen, is absorbed on a silicon substrate. A plurality of insulating layers sandwiched between epitaxial silicon forms a barrier composite.

Despite the existence of such approaches, further enhancements may be desirable for using advanced semiconductor materials and processing techniques to achieve improved performance in semiconductor devices.

### SUMMARY

A method for making a semiconductor device may include growing ²⁸Si on a semiconductor layer, intermixing the ²⁸Si in the semiconductor layer, and thinning the semiconductor layer after intermixing. The method may further include repeating growing, intermixing, and thinning until a concentration of ²⁸Si in the semiconductor layer reaches a target concentration.

In an example embodiment, intermixing may comprise forming at least one non-semiconductor monolayer on the semiconductor layer. By way of example, forming the at least one non-semiconductor monolayer may comprise forming a superlattice including a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. In accordance with another example, the at least one non-semiconductor monolayer may comprise oxygen. In still another embodiment, intermixing may comprise annealing the semiconductor layer and ²⁸Si.

In an example implementation, the method may further include forming a superlattice layer adjacent the semiconductor layer after the concentration of ²⁸Si in the semiconductor layer reaches the target concentration. The superlattice layer may include a plurality of stacked groups of layers, with each group of layers including a plurality of stacked base semiconductor monolayers defining a base semiconductor portion, and at least one non-semiconductor monolayer constrained within a crystal lattice of adjacent base semiconductor portions. By way of example, the base semiconductor monolayers may comprise silicon, and the at least one non-semiconductor monolayer may comprise oxygen.

In one implementation, the method may further include forming a metal oxide semiconductor field effect transistor (MOSFET) above the semiconductor layer after the concentration of ²⁸Si in the semiconductor layer reaches the target concentration. In another example implementation, the method may include forming a quantum bit (qubit) device above the semiconductor layer after the concentration of ²⁸Si in the semiconductor layer reaches the target concentration.

### BRIEF DESCRIPTION OF THE DRAWINGS

FIG. 1 is a greatly enlarged schematic cross-sectional view of a superlattice for use in a semiconductor device in accordance with an example embodiment.

FIG. 2 is a perspective schematic atomic diagram of a portion of the superlattice shown in FIG. 1.

FIG. 3 is a greatly enlarged schematic cross-sectional view of another embodiment of a superlattice in accordance with an example embodiment.

FIG. 4 is a chart illustrating an example sequence of fabricating an enhanced ²⁸Si layer in accordance with an example embodiment.

FIG. 5 is a schematic block diagram of a semiconductor device including an enriched ²⁸Si epitaxial layer formed on a superlattice in accordance with an example embodiment.

FIG. 6 is a schematic block diagram of a semiconductor device including a MOSFET formed on an enriched ²⁸Si epitaxial layer in accordance with an example embodiment.

FIG. 7 is a schematic block diagram of a semiconductor device including a quantum bit (qubit) device formed on an enriched ²⁸Si epitaxial layer in accordance with an example embodiment.

FIG. 8 is a schematic block diagram of an alternative embodiment of the semiconductor device of FIG. 5.

FIG. 9 is a schematic block diagram of another alternative embodiment of the semiconductor device of FIG. 5.

FIG. 10 is a schematic block diagram of still another alternative embodiment of the semiconductor device of FIG. 5.

FIG. 11 is a flow diagram illustrating an example approach for fabricating a semiconductor device such as those of FIGS. 6-10 including an enriched ²⁸Si epitaxial layer.

### DETAILED DESCRIPTION

Example embodiments will now be described more fully hereinafter with reference to the accompanying drawings, in which the example embodiments are shown. The embodiments may, however, be implemented in many different forms and should not be construed as limited to the specific examples set forth herein. Rather, these embodiments are provided so that this disclosure will be thorough and complete. Like numbers refer to like elements throughout, and prime notation is used to indicate similar elements in different embodiments.

Generally speaking, the present disclosure relates to semiconductor devices having an enhanced semiconductor superlattice therein to provide performance enhancement characteristics. The enhanced semiconductor superlattice may also be referred to as an “MST” layer or “MST technology” in this disclosure.

More particularly, the MST technology relates to advanced semiconductor materials such as the superlattice 25 described further below. In prior work, Applicant theorized that certain superlattices as described herein reduce the effective mass of charge carriers, and that this accordingly leads to higher charge carrier mobility. See, e.g., U.S. Pat. No. 6,897,472, which is hereby incorporate herein in its entirety by reference.

Further development by Applicant has established that the presence of MST layers may advantageously improve the mobility of free carriers in semiconductor materials, e.g., at interfaces between silicon and insulators like SiO₂ or HfO₂. Applicant theorizes, without wishing to be bound thereto, that this may occur due to various mechanisms. One mechanism is by reducing the concentration of charged impurities proximate to the interface, by reducing the diffusion of these impurities, and/or by trapping the impurities so they do not reach the interface proximity. Charged impurities cause Coulomb scattering, which reduces mobility. Another mechanism is by improving the quality of the interface. For example, oxygen emitted from an MST film may provide oxygen to a Si—SiO₂ interface, reducing the presence of sub-stochastic SiOₓ. Alternately, the trapping of interstitials by MST layers may reduce the concentration of interstitial silicon proximate to the Si—SiO₂ interface, reducing the tendency to form sub-stochastic SiOₓ. Sub-stochastic SiOₓ at the Si—SiO₂ interface is known to exhibit inferior insulating properties relative to stochastic SiOₓ. Reducing the amount of sub-stochastic SiOₓ at the interface more effectively confines free carriers (electrons or holes) in the silicon, and thus improves the mobility of these carriers due to electric fields applied parallel to the interface, as is standard practice in field effect transistor (“FET”) structures. Scattering due to the direct influence of the interface is called “surface-roughness scattering”, which may advantageously be reduced by the proximity of MST layers followed by anneals or during thermal oxidation.

In addition to the enhanced mobility characteristics of MST structures, they may also be formed or used in such a manner that they provide piezoelectric, pyroelectric, and/or ferroelectric properties that are advantageous for use in a variety of different types of devices, as discussed further in U.S. Pat. No. 7,517,702, which is also from the present Applicant and is hereby incorporated herein in its entirety by reference.

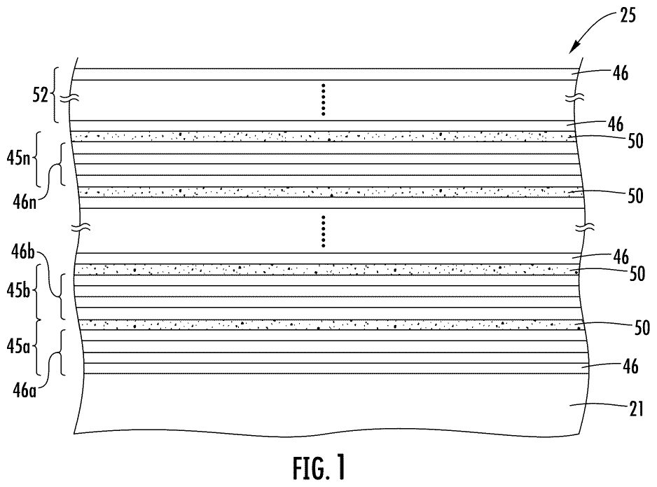

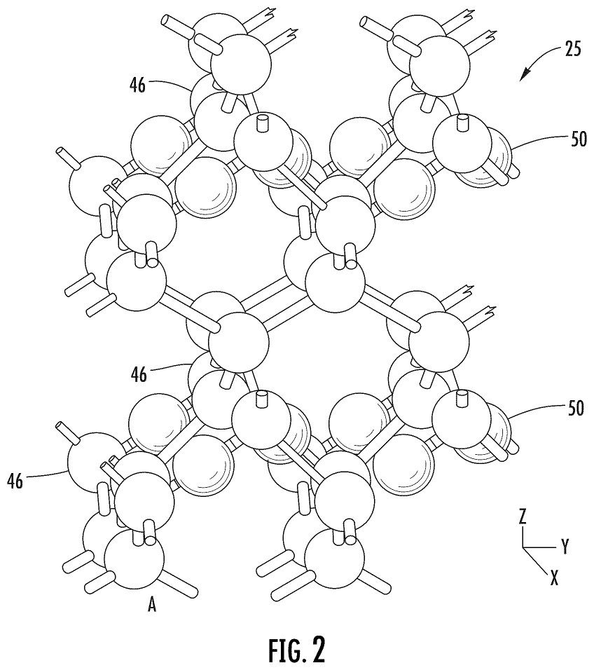

Referring now to FIGS. 1 and 2, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 1.

Each group of layers 45a-45n of the superlattice 25 illustratively includes a plurality of stacked base semiconductor monolayers 46 defining a respective base semiconductor portion 46a-46n and a non-semiconductor monolayer(s) 50 thereon. The non-semiconductor monolayers 50 are indicated by stippling in FIG. 1 for clarity of illustration.

The non-semiconductor monolayer 50 illustratively includes one non-semiconductor monolayer constrained within a crystal lattice of adjacent base semiconductor portions. By “constrained within a crystal lattice of adjacent base semiconductor portions” it is meant that at least some semiconductor atoms from opposing base semiconductor portions 46a-46n are chemically bound together through the non-semiconductor monolayer 50 therebetween, as seen in FIG. 2. Generally speaking, this configuration is made possible by controlling the amount of non-semiconductor material that is deposited on semiconductor portions 46a-46n through atomic layer deposition techniques so that not all (i.e., less than full or 100% coverage) of the available semiconductor bonding sites are populated with bonds to non-semiconductor atoms, as will be discussed further below. Thus, as further monolayers 46 of semiconductor material are deposited on or over a non-semiconductor monolayer 50, the newly deposited semiconductor atoms will populate the remaining vacant bonding sites of the semiconductor atoms below the non-semiconductor monolayer.

In other embodiments, more than one such non-semiconductor monolayer may be possible. It should be noted that reference herein to a non-semiconductor or semiconductor monolayer means that the material used for the monolayer would be a non-semiconductor or semiconductor if formed in bulk. That is, a single monolayer of a material, such as silicon, may not necessarily exhibit the same properties that it would if formed in bulk or in a relatively thick layer, as will be appreciated by those skilled in the art.

Moreover, this superlattice structure may also advantageously act as a barrier to dopant and/or material diffusion between layers vertically above and below the superlattice 25. These properties may thus advantageously allow the superlattice 25 in one example implementation to provide an interface for high-K dielectrics which not only reduces diffusion of the high-K material into the channel region, but which may also advantageously reduce unwanted scattering effects and improve device mobility, as will be appreciated by those skilled in the art.

The superlattice 25 also illustratively includes a cap layer 52 on an upper layer group 45n. The cap layer 52 may comprise a plurality of base semiconductor monolayers 46. The cap layer 52 may have between 2 to 100 monolayers of the base semiconductor, and, more preferably between 10 to 50 monolayers.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each non-semiconductor monolayer 50 may comprise a non-semiconductor selected from the group consisting of oxygen, nitrogen, fluorine, carbon and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing as will be appreciated by those skilled in the art.

It should be noted that the term monolayer is meant to include a single atomic layer and also a single molecular layer. It is also noted that the non-semiconductor monolayer 50 provided by a single monolayer is also meant to include a monolayer wherein not all of the possible sites are occupied (i.e., there is less than full or 100% coverage). For example, with particular reference to the atomic diagram of FIG. 2, a 4/1 repeating structure is illustrated for silicon as the base semiconductor material, and oxygen as the energy band-modifying material. Only half of the possible sites for oxygen are occupied in the illustrated example.

In other embodiments and/or with different materials this one-half occupation would not necessarily be the case as will be appreciated by those skilled in the art. Indeed, it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

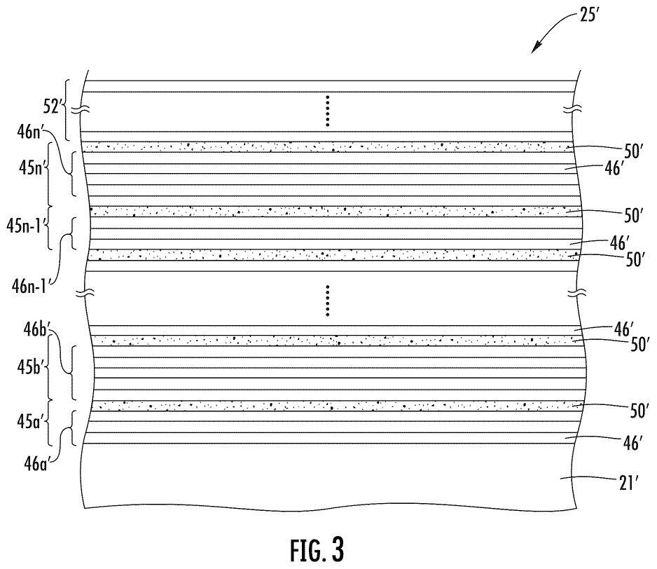

Referring now additionally to FIG. 3, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The non-semiconductor monolayers 50′ may each include a single monolayer. For such a superlattice 25′ including Si/O, the enhancement of charge carrier mobility is independent of orientation in the plane of the layers. Those other elements of FIG. 3 not specifically mentioned are similar to those discussed above with reference to FIG. 1 and need no further discussion herein.

In some device embodiments, all of the base semiconductor portions of a superlattice may be a same number of monolayers thick. In other embodiments, at least some of the base semiconductor portions may be a different number of monolayers thick. In still other embodiments, all of the base semiconductor portions may be a different number of monolayers thick.

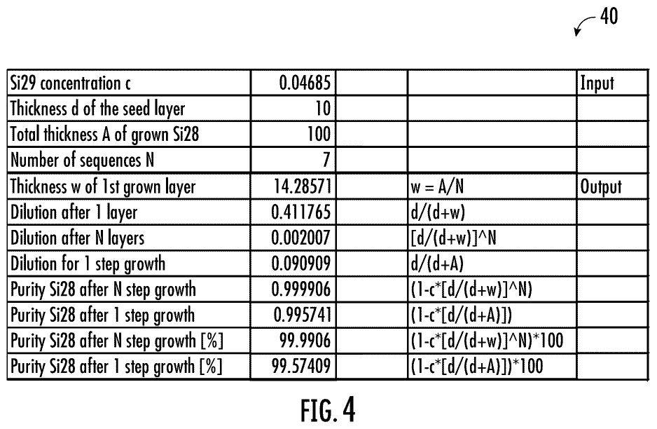

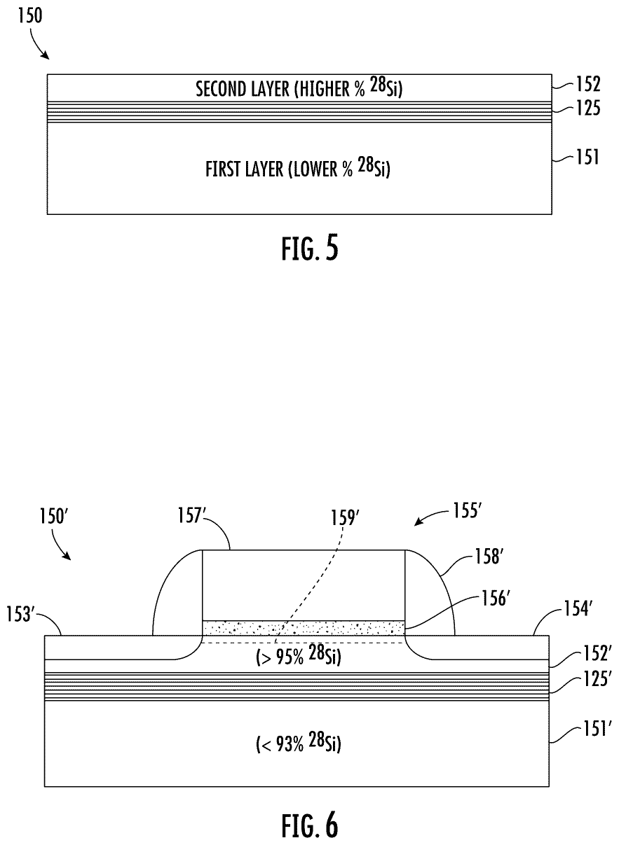

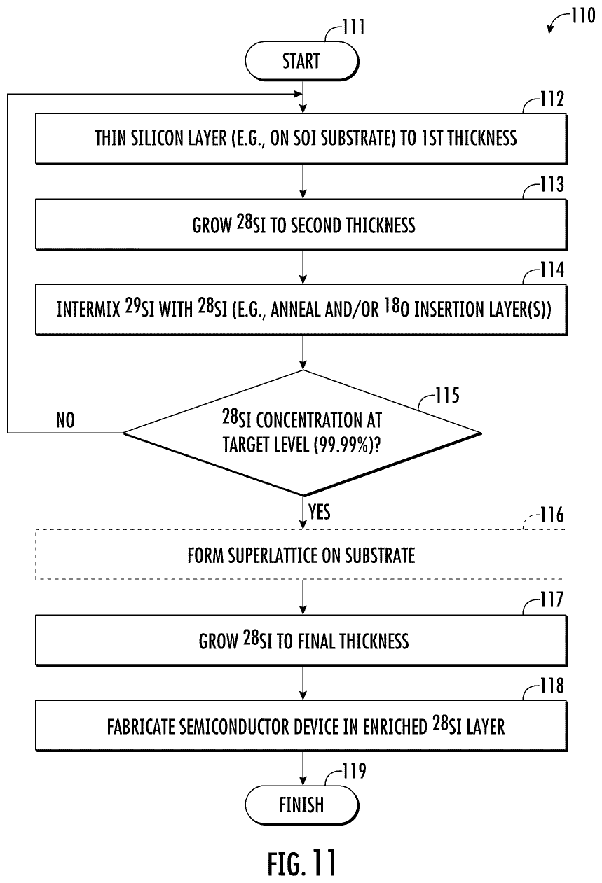

Turning now to the chart 40 of FIG. 4, FIG. 5, and the flow diagram 110 of FIG. 11, an example approach for fabricating a wafer 150 including an enhanced silicon 28 (also referenced as ²⁸Si or Si28 herein) layer 152 on a substrate 151 and subsequent circuit devices is now described. In some embodiments, the above-described MST films or superlattices 125 may be utilized as a buffer layer between the substrate and the ²⁸Si layer, as will be discussed further below, although an MST buffer layer is not required in all embodiments.

By way of background, silicon has multiple natural stable isotopes. The most abundant natural stable isotopes are ²⁸Si (92.23%), ²⁹Si (4.67%), and ³⁰Si (3.10%). There are several advantages to ²⁸Si substrates. For example, they have higher thermo-conductivity (better heat dissipation), and a higher decoherence time which is useful for qubit applications.

On the other hand, there is a substantial cost related to the purification of ²⁸Si, and thus production of ²⁸Si in large quantities (e.g., as a substrate) can be cost prohibitive. As a result, some attempts have been made to form ²⁸Si layers on top of a semiconductor layers such as natural silicon substrates (i.e., having 92.23% or less ²⁸Si). However, due to silicon interdiffusion, a relatively thick ²⁸Si epitaxial layer still needs to be grown on the substrate. In still another approach, to prevent silicon intermixing, designs utilizing a silicon-on-insulator (SOI) approach have also been proposed. While this allows for a relatively thin ²⁸Si layer, the SOI technology used for this implementation is costly as well.

In the illustrated example, beginning at Block 111, the process starts with a standard SOI substrate having a first percentage of ²⁸Si (e.g., around 93%) in the upper silicon layer, at Block 112. The upper silicon layer on a standard SOI wafer typically has a thickness on the order of 220 nm or so, which is higher than desired for the present approach. As such, the thickness of the silicon layer is reduced (e.g., by etching or CMP) to a first thickness, which may be in a rage of 5-30 nm, for example, at Block 113. Thinning may occur at the time of manufacture of the wafer, or later when ²⁸Si and subsequent device processing are to be performed. It should be noted that, in some embodiments, a substrate with an MST film and cap layer may be used as the starting point instead of an SOI wafer, if desired, and the cap layer may similarly be formed or thinned to the first thickness. A relatively small starting thickness helps to more quickly increase the concentration of ²⁸Si to the desired level during the process, as a thinner seed layer will have a lower concentration of other silicon isotopes besides ²⁸Si to be removed during the process.

In one example implementation, the etch used for thinning the silicon layer may be an HCl etch. However, one side effect of etching to such a thin seed layer with an etchant such as HCl is that this may cause spin contaminants to be introduced into the first layer 151. As explained above, the MST layer 125 functions as a buffer or gettering layer to advantageously help prevent such contaminants from reaching the first layer 151. An SOI insulating layer may also help block contaminants from reaching the first layer 151 as well.

At Block 113, enriched ²⁸Si may then be epitaxially deposited on the seed layer to a desired thickness, which in the example of FIG. 4 is 100 nm, although different thicknesses may be used in different embodiments. Furthermore, an intermixing step is also performed to cause ²⁹Si from the thinned silicon layer to intersperse or intermix throughout the new ²⁸Si growth. One approach to intermixing is to perform an anneal. Another technique to encourage intermixing is to form an optional MST layer (or a single oxygen-insertion layer, in some embodiments) either before or during the ²⁸Si growth. More particularly, MST films may naturally cause enhanced ²⁸Si/²⁹Si intermixing by drawing in ²⁹Si isotopes from the immediate vicinity into the superlattice where they intermix with the ²⁸Si. The base semiconductor used for the MST film may be the enriched ²⁸Si, and this MST film may be sacrificial in that it is removed during the thinning of the silicon layer. In some embodiments, using an MST film (or oxygen-insertion layer) may accordingly reduce the time and/or duration of, or potentially eliminate the need for, annealing.

Furthermore, oxygen may advantageously be used as the non-semiconductor in an intermixing MST film (or stand-alone oxygen insertion layer). More particularly, there are three main isotopes of oxygen, namely ¹⁶O, ¹⁷O and ¹⁸O. The most common (99.8%) is ¹⁶O. Both ¹⁶O and ¹⁸O have no nuclear spin, whereas ¹⁷O does have a nuclear spin. As such, in some applications it may be advantageous to use isotopically purified oxygen (i.e., ¹⁶O or ¹⁸O) without ¹⁷O. However, for other applications any oxygen variation may be sufficient, particularly if it is being used for a sacrificial layer. Further details regarding the use of ¹⁸O in MST films may be found in U.S. Pat. Nos. 11,682,712 and 11,728,385, also from the present Applicant, which are hereby incorporated herein in their entireties by reference.

The steps illustrated at Blocks 112-114 are repeated until the concentration of enriched ²⁸Si in the second layer 152 reaches the desired target level (Block 115), which in the present example is 99.99%. As shown in the attached Appendix A, for Si qubits with a dopant or quantum dot spin state, the ²⁹Si nuclear spin is the main source of decoherence, and achieving 99.99% ²⁸Si purity overcomes this decoherence, which is why it was used as the target level for the present example. However, in other embodiments, other ²⁸Si purity levels may be used.

As seen in the chart 40, each successive epitaxial deposition of enriched ²⁸Si and subsequent etch drives the concentration of ²⁹Si in the layer down, while correspondingly driving the concentration of ²⁸Si closer to the target level. More particularly, the ²⁹Si isotopes in the seed layer intermix with the ²⁸Si isotopes during the deposition such that they are disbursed throughout the layer. Thus, when etched back to the relatively small target thickness (here 10 nm), the concentration of ²⁹Si isotopes (or other type of semiconductor isotopes if a different type seed layer is used) remaining may be quickly diminished. In the illustrated example, after dividing the growth cycle into a given number of iterations N (which in the present case is 7), the purity of ²⁸Si in the second layer 152 reaches 99.9906% after the last cycle, exceeding the target of 99.99%. By way of comparison, if a single ²⁸Si deposition was performed in which the same total amount of ²⁸Si was deposited with no intermediate etching/thinning as described above, the resulting concentration or purity of the ²⁸Si would only be 99.5741%, less than the target amount desired to avoid ²⁹Si decoherence.

After the appropriate number of iterations have been performed to achieve the target level of ²⁸Si, in some embodiments an MST layer may optionally be formed (Block 116). This optional MST layer may be used as a dopant barrier and/or to provide enhanced conductivity (e.g., in a channel region), as discussed further above. Irrespective of whether an optional MST layer is used, the final ²⁸Si enriched layer 152 may be grown to the desired thickness for an active device layer (Block 117), in which further processing steps may be performed to define different types of semiconductor circuitry devices (Block 118), examples of which will be described below with reference to FIGS. 6-10. Thus, the second percentage of ²⁸Si in the layer 152 is higher than the first percentage of ²⁸Si in the first layer 151, defining an isotropically enriched, high concentration ²⁸Si layer to provide the above-described technical advantages, yet while avoiding the high costs associated with conventional approaches of thick ²⁸Si formation. The method of FIG. 11 illustratively concludes at Block 119.

Referring now to FIG. 6, in accordance with one example implementation of a semiconductor device 150′, the additional circuitry illustratively includes one or more MOSFET devices (e.g., CMOS) associated with the second silicon layer 152′. More particularly, the MOSFET illustratively includes spaced apart source and drain regions 153′, 154′ in the second single crystal silicon layer 152′ defining a channel 159′ therebetween, and a gate 155′ including a gate dielectric layer 156′ (e.g., SiO₂) overlying the channel and a gate electrode 157′ overlying the gate dielectric layer. Sidewall spacers 158′ are also formed adjacent the gate 155′. In this example, the first silicon layer 151′ has less than 93% ²⁸Si, while the second silicon layer 152′ has at least the target purity of 99.99% ²⁸Si, although different percentages may be used in different embodiments.

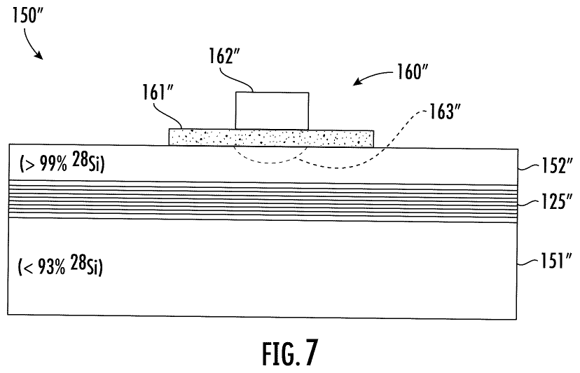

Turning to FIG. 7, in accordance with another example implementation a semiconductor device 150″ illustratively includes one or more quantum bit (qubit) devices 160″ associated with the second silicon layer 152″. More particularly, the quantum bit device 160″ illustratively includes an insulating layer 161″ (e.g., SiO₂) on the second silicon layer 152″, and a gate electrode 160″ on the insulating layer defining a hole or electron isolation area 163″ beneath the gate electrode in the second single crystal silicon layer. In this example, the first silicon layer 151″ has less than 93% ²⁸Si, while the second silicon layer 152″ has at least the target purity of 99.99% ²⁸Si, although different percentages may be used in different embodiments. Further implementation details and examples of quantum devices which may be used are set forth in the following references, which are hereby incorporated herein in their entireties by reference: U.S. Pat. No. 9,886,668 to Dzurak et al; “Coherent spin control of s-, p-, d- and f-electrons in a silicon quantum dot” by Leon et al. (Nature Communications, (2020) 11:797); “Single-spin qubits in isotropically enriched silicon at low magnetic field” by Zhao et al. (Nature Communications, (2019) 10:5500); and “Silicon CMOS architecture for a spin-based quantum computer” by Veldhorst et al. (Nature Communications, (2017) 8:1766).

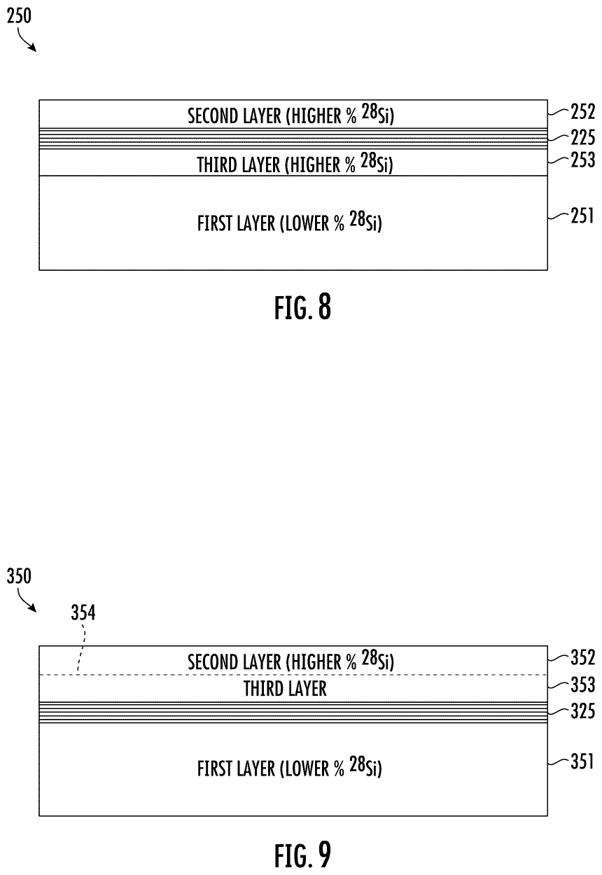

Turning now to FIG. 8, another example embodiment of a semiconductor device 250 illustratively includes a first single crystal silicon layer 251 (e.g., a substrate) having a first percentage of ²⁸Si, a superlattice 225, and a second single crystal silicon layer 252 (e.g., an active device layer) similar to those discussed above with respect to FIG. 5. However, in the present example a third single crystal semiconductor layer 253 is epitaxially grown on the first layer 253, and the superlattice 225 is formed on the third single crystal semiconductor layer. More particularly, the third single crystal semiconductor layer 253 has a third percentage of ²⁸Si which is also higher than the first percentage of ²⁸Si, defining an isotropically enriched, high concentration ²⁸Si layer. For example, the third single crystal semiconductor layer 253 may be used as a seed layer to start the transition from the lower (first) percentage of ²⁸Si to the higher (second) percentage ²⁸Si before depositing the superlattice layer 225. In an example embodiment, the concentration of ²⁸Si may be graded or increase from the bottom of the layer to the top, or the concentration of ²⁸Si may be relatively consistent across the third layer in some embodiments.

The silicon monolayers 46 of the superlattice 225 may also be formed with enriched ²⁸Si. In this regard, it should be noted that in some embodiments, the third layer 253 may be absent, but the transition to the enriched ²⁸Si may take place in the silicon monolayers 46 of the superlattice 225. That is, some or all of the monolayers 46 of the superlattice 225 may be formed with enriched ²⁸Si, with or without the third layer 225.

Turning now to FIG. 9, in another example embodiment a semiconductor device 350 illustratively includes a first single crystal silicon layer 351 (e.g., a substrate) having a first percentage of ²⁸Si, a superlattice 325, and a second single crystal silicon layer 352 (e.g., an active device layer) similar to those discussed above with respect to FIG. 5. However, in the present example a third single crystal semiconductor layer 353 is epitaxially grown on the superlattice 325, and is accordingly between the superlattice and the second single crystal semiconductor layer 352.

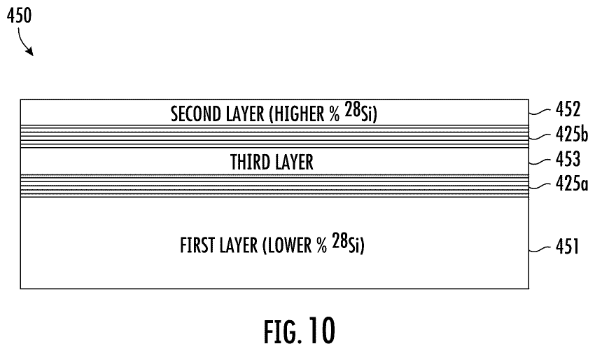

Referring additionally to FIG. 10, an example semiconductor device 450 illustratively includes a first single crystal silicon layer 451 (e.g., a substrate) having a first percentage of ²⁸Si, a first superlattice 425a on the first single crystal silicon layer, a third silicon layer 453 on the first superlattice, the second superlattice 425b on the third silicon layer, and a second single crystal silicon layer 452 (e.g., an active device layer). The first, second, and third layers 451-453 may be similar to layers 351-353 discussed above with respect to FIG. 9.

The foregoing embodiments provide a relatively low-cost approach for growing purified ²⁸Si layers on a substrate. In addition to the above-noted advantages of ²⁸Si, the above-described configurations provide additional advantages as a result of the incorporated superlattice(s), as discussed further above.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that other modifications and embodiments are intended to be included within the scope of the appended claims.

1. A method for making a semiconductor device comprising:
growing ²⁸Si on a semiconductor layer;
intermixing the ²⁸Si in the semiconductor layer;
thinning the semiconductor layer after intermixing; and
repeating growing, intermixing, and thinning until a concentration of ²⁸Si in the semiconductor layer reaches a target concentration.

2. The method of claim 1 wherein intermixing comprises forming at least one non-semiconductor monolayer on the semiconductor layer.

3. The method of claim 2 wherein forming the at least one non-semiconductor monolayer comprises forming a superlattice comprising a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

4. The method of claim 2 wherein the at least one non-semiconductor monolayer comprises oxygen.

5. The method of claim 1 wherein intermixing comprises annealing the semiconductor layer and ²⁸Si.

6. The method of claim 1 further comprising forming a superlattice layer adjacent the semiconductor layer after the concentration of ²⁸Si in the semiconductor layer reaches the target concentration, the superlattice comprising a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

7. The method of claim 6 wherein the base semiconductor monolayers comprise silicon.

8. The method of claim 6 wherein the at least one non-semiconductor monolayer comprises oxygen.

9. The method of claim 1 further comprising forming a metal oxide semiconductor field effect transistor (MOSFET) above the semiconductor layer after the concentration of ²⁸Si in the semiconductor layer reaches the target concentration.

10. The method of claim 1 further comprising forming a quantum bit (qubit) device above the semiconductor layer after the concentration of ²⁸Si in the semiconductor layer reaches the target concentration.

11. A method for making a semiconductor device comprising:
growing ²⁸Si on a semiconductor layer;
intermixing the ²⁸Si in the semiconductor layer by forming at least one non-semiconductor monolayer on the semiconductor layer;
thinning the semiconductor layer after intermixing;
repeating growing, intermixing, and thinning until a concentration of ²⁸Si in the semiconductor layer reaches a target concentration; and
forming a metal oxide semiconductor field effect transistor (MOSFET) above the semiconductor layer after the concentration of ²⁸Si in the semiconductor layer reaches the target concentration.

12. The method of claim 11 wherein forming the at least one non-semiconductor monolayer comprises forming a superlattice comprising a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

13. The method of claim 11 wherein the at least one non-semiconductor monolayer comprises oxygen.

14. The method of claim 11 further comprising forming a superlattice layer adjacent the semiconductor layer after the concentration of ²⁸Si in the semiconductor layer reaches the target concentration, the superlattice comprising a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

15. The method of claim 14 wherein the base semiconductor monolayers comprise silicon, and the at least one non-semiconductor monolayer comprises oxygen.

16. A method for making a semiconductor device comprising:
growing ²⁸Si on a semiconductor layer;
intermixing the ²⁸Si in the semiconductor layer by forming at least one non-semiconductor monolayer on the semiconductor layer;
thinning the semiconductor layer after intermixing;
repeating growing, intermixing, and thinning until a concentration of ²⁸Si in the semiconductor layer reaches a target concentration; and
forming a quantum bit (qubit) device above the semiconductor layer after the concentration of ²⁸Si in the semiconductor layer reaches the target concentration.

17. The method of claim 16 wherein forming the at least one non-semiconductor monolayer comprises forming a superlattice comprising a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

18. The method of claim 16 wherein the at least one non-semiconductor monolayer comprises oxygen.

19. The method of claim 16 further comprising forming a superlattice layer adjacent the semiconductor layer after the concentration of ²⁸Si in the semiconductor layer reaches the target concentration, the superlattice comprising a plurality of stacked groups of layers, with each group of layers comprising a plurality of stacked base semiconductor monolayers defining a base semiconductor portion, and at least one non-semiconductor monolayer constrained within a crystal lattice of adjacent base semiconductor portions.

20. The method of claim 19 wherein the base semiconductor monolayers comprise silicon, and the at least one non-semiconductor monolayer comprises oxygen.
